(19) United States
(12) Patent Application Publication
(10) Pub. No.: US 2017/0025551 A1
(43) Pub. Date: Jan. 26, 2017

(54) DIODE

(71) Applicant: TOYOTA JIDOSHA KABUSHIKI KAISHA, Toyota-shi (JP)

(72) Inventor: Wittawat YAMWONG, Bangkok (TH)

(73) Assignee: TOYOTA JIDOSHA KABUSHIKI KAISHA, Toyota-shi (JP)

(21) Appl. No.: 15/185,972

(22) Filed: Jun. 17, 2016

(30) Foreign Application Priority Data
Jul. 21, 2015 (JP) 2015-144021

(51) Int. Cl. H01L 29/872

(52) U.S. Cl. CPC H01L 29/872

(57) ABSTRACT

A diode includes a cell field, an intermediate field and a peripheral filed. The cell filed includes at least one first anode region of p-type; at least one pillar region of n-type and in contact with the anode electrode; a barrier region of n-type and in contact with the first anode region and the pillar region from a rear surface side; and a first intermediate region of p-type, in contact with the barrier region from the rear surface side. The intermediate field includes: a second anode region of p-type and in Ohmic contact with the anode electrode, a hole suppression region being in contact with the anode electrode; and a second intermediate region of p-type, in contact with the second anode region and the hole suppression region from the rear surface side. The barrier region is not located in the intermediate field.

### CROSS-REFERENCE TO RELATED APPLICATION

This application claims priority to Japanese Patent Application No. 2015-144021 filed on Jul. 21, 2015, the entire contents of which are hereby incorporated by reference into the present application.

### TECHNICAL FIELD

The technique disclosed herein related to a diode.

### DESCRIPTION OF RELATED ART

Japanese Patent Application Publication No. 2013-048230 discloses a diode. In this diode, an anode electrode is disposed on a front surface of a semiconductor substrate, and a cathode electrode is disposed on a rear surface of the semiconductor substrate. Anode regions, pillar regions, a barrier region, an intermediate region (p-electric field expansion preventing region), and a cathode region are provided in the semiconductor substrate. The anode regions are of a p-type, and makes Ohmic contact with the anode electrode. The pillar regions are of an n-type, and makes contact with the anode electrode. The anode regions and the pillar regions are disposed such that they are alternately exposed on the front surface of the semiconductor substrate. The barrier region is of the n-type, and makes contact with the anode regions and the pillar regions from their rear surface side. The intermediate region is of the p-type, and makes contact with the barrier region from its rear surface side. The intermediate region is separated from the anode regions by the harrier region. The cathode region is of the n-type, makes contact with the intermediate region from its rear surface side, and also makes contact with the cathode electrode.

In this diode, electrons begin to flow from the cathode electrode to the anode electrode through the cathode region, the intermediate region, the barrier region, and the pillar region when a potential of the anode electrode is increased. That is, the electrons flow in the diode at a stage where the potential of the anode electrode is still in the process of increasing. Since the barrier region is connected to the anode electrode via the pillar regions, a potential difference between the barrier region and the anode electrode at this stage is small. Due to this, a potential difference is less likely to be generated in a pn junction at an interface between the barrier region and the anode regions, so this pn junction at this stage does not turn on. When the potential of the anode electrode is further increased, current is increased by the aforementioned electrons, and the potential difference between the barrier region and the anode electrode becomes larger. When this potential difference reaches a predetermined potential difference, the pn junction at the interface between the barrier region and the anode region turns on, and holes flow from the anode electrode to the cathode region through the anode region, the barrier region, and the intermediate region. As above, in this diode, the electrons flow through the barrier region and the pillar region before when the pn junction at the interface between the barrier region and the anode region turns on. Due to this, a turn-on timing of the pn junction is delayed, and the holes are prevented from flowing into the cathode region. Thus, smaller number of holes are discharged from the cathode region to the anode electrode upon a reverse recovery operation of this diode. Due to this, in this diode, reverse recovery current is small and loss generated upon the reverse recovery operation can be suppressed.

### BRIEF SUMMARY

In a general diode, a range that is a part of the front surface of the semiconductor substrate makes contact with the anode electrode, and in a periphery thereof, the front surface of the semiconductor substrate is covered by an insulating layer. The anode electrode does not make contact with the semiconductor substrate in the range covered by the insulating layer. Hereinbelow, the range where the semiconductor substrate and the anode electrode make contact will be termed an element field, and the range where the semiconductor substrate and the anode electrode do not make contact will be termed a peripheral field.

The diode of Japanese Patent Application Publication No. 2013-048230 is considered to be provided with the aforementioned element field and peripheral field. Thus, in the diode of Japanese Patent Application Publication No. 2013-048230, the holes diffuse in the cathode region in the peripheral field during when the pn junction is turned on. Due to this, when the diode performs a reverse recovery operation, not only holes existing in the element field but also holes existing in the peripheral field are also discharged to the anode electrode. Due to this, reverse recovery current concentrates more easily in a range within the element field proximate to the peripheral field. When the reverse recovery current concentrates in the range within the element field proximate to the peripheral field, a barrier region serves as a barrier to the reverse recovery current, thus a potential of the intermediate region rises. If the potential of the intermediate region becomes extremely high, there is a ease where an npn transistor (parasitic transistor) configured of the barrier region, the intermediate region, and the cathode region turns on. If this parasitic transistor turns on, a phenomenon in which carriers are injected from the electrode to the semiconductor substrate occurs, as a result of which the reverse recovery current becomes large and the loss generated upon the reverse recovery operation cannot be controlled. In this disclosure, a technique that allows to suppress a parasitic transistor from turning on in a diode including a pillar region, a barrier region, an intermediate region, and a cathode region.

A diode disclosed herein comprises: a semiconductor substrate; an anode electrode disposed on a front surface of the semiconductor substrate; and a cathode electrode disposed on a rear surface of the semiconductor substrate. The semiconductor substrate comprises, in a plan view, a cell field; an intermediate field located outside the cell field; and a peripheral field located outside the intermediate field. The anode electrode is in contact with the front surface of the semiconductor substrate in the cell field and the intermediate field, but is not in contact with the front surface of the semiconductor substrate in the peripheral field. The cell field comprises: at least one first anode region being of a p-type and in Ohmic contact with the anode electrode, the first anode region including portions exposed on the front surface of the semiconductor substrate; at least one pillar region being of an n-type and in contact with the anode electrode, the pillar region including portions exposed on the front surface of the semiconductor substrate. The portions of the first anode region and the portions of the pillar region are alternately exposed on the front surface when viewed in a specific section of the semiconductor substrate. The cell field further comprises a barrier region being of the n-type and in contact with the portions of the first anode region and the portions of the pillar region from a rear surface side; and a first intermediate region being of the p-type, in contact with the barrier region from the rear surface side, and separated from the first anode region by the barrier region. The intermediate field comprises: a second anode region being of the p-type and in Ohmic contact with the anode electrode; a hole suppression region being in contact with the anode electrode; and a second intermediate region being of the p-type, in contact with the second anode region and the bole suppression region from the rear surface side, and in contact with the first intermediate region. The barrier region is not located in the intermediate field. A barrier structure is provided on a pathway from the anode electrode to the second intermediate region via the hole suppression region in the barrier structure, a barrier in a direction from the anode electrode toward the second intermediate region is larger than a barrier in a direction from the second intermediate region toward the anode electrode. A cathode region being of the n-type, in contact with the first intermediate region and the second intermediate region from the rear surface side, and in contact with the cathode electrode is provided in a range across the cell field, the intermediate field, and the peripheral field.

Notably, the at least one first anode region mentioned above may be configured of a single p-type region, or may be configured of a plurality of p-type regions that is separate from one another. Further, the at least one pillar region may be configured of a single n-type region, or may be configured of a plurality of n-type regions that is separate from one another. Further, in this disclosure, a barrier means a potential difference that is required for carriers to pass through a barrier structure.

Firstly, a forward operation of this diode (operation in a case where a potential of the anode electrode is higher than a potential of the cathode electrode) will be described. In the cell field, holes flow from the anode electrode into the cathode region through the first anode region, the barrier region, and the first intermediate region. However, in the cell field, the inflow of the holes from the anode electrode into the cathode region is suppressed by the barrier region and the pillar region. In the intermediate field, the holes flow from the anode electrode into the cathode region through the second anode region and the second intermediate region. No barrier region is provided inside the intermediate field. Due to this, in the intermediate field, the holes flow into the cathode region easier than in the cell filed. However, the hole suppression region is provided inside the intermediate filed. Since a barrier in a pathway from the anode electrode to the second intermediate region via the hole suppression region is high, hardly any holes flow in the pathway including the hole suppression region. Further, with the hole suppression region being provided, a contact area of the anode electrode and the second anode region is made small. Due to this, the inflow of the holes into the cathode region is somewhat suppressed also in the intermediate field. A part of the holes having flown into the cathode region diffuses to the peripheral field.

Next, a reverse recovery operation of this diode will be described. When the potential of the cathode electrode becomes higher than the potential of the anode electrode, the holes existing in the cathode region are discharged to the anode electrode. Due to the holes discharged as above, the reverse recovery current flows in the diode. In the cell field, since the holes in the cathode region is discharged to the anode electrode through the first intermediate region, the barrier region, and the first anode region. In the cell field, since the holes flowing into the cathode region upon the forward operation is small in amount, the holes discharged to the anode electrode upon the reverse recovery operation is likewise small in amount. Thus, the reverse recovery current flowing in the cell field does not increase the potential of the first intermediate region so much. In the intermediate field, the holes in the cathode region flow to the anode electrode through the second intermediate region and the second anode region. At this occasion, not only the holes existing in the cathode region in the intermediate field but also the holes existing in the cathode region in the peripheral field are discharged to the anode electrode through the intermediate field (that is, the second intermediate region and the second anode region). That is, the reverse recovery current flows in high concentration in the intermediate field. However, the intermediate field is not provided with a barrier region, and the second intermediate region makes direct contact with the second anode region. Due to this, even if the reverse recovery current flows in high concentration in the intermediate field, the potential of the second intermediate region does not increase so much. Further, since the inflow of the holes into the cathode region upon the forward operation is somewhat suppressed by the hole suppression region, so the reverse recovery current that flows in the second intermediate field upon the reverse recovery operation is likewise suppressed to some degree. Due to this as well, the increase in the potential of the second intermediate region is suppressed. As above, since the increase in the potential of the second intermediate region is suppressed, the increase in the potential of the first intermediate region making contact with the second intermediate region is also suppressed. As above, the reverse recovery current flowing in the intermediate field does not so much increase the potential of the first intermediate region. As above, since the potential of the first intermediate region does not increase so much upon the reverse recovery operation, the parasitic transistor in the cell field (that is, the npn transistor configured by the barrier region, the first intermediate region, and the cathode region) is less likely to turn on. According to this diode, the parasitic transistor in the cell field is suppressed to be turned on. Thus, a loss generated by the parasitic transistor being turned on can be suppressed.

### BRIEF DESCRIPTION OF DRAWINGS

FIG. 1 is a plan view of a diode 10 of a first embodiment;

FIG. 2 is a vertical cross sectional view along a line A-A (straight line extending in an x direction) of FIG. 1;

FIG. 3 is a vertical cross sectional view along the line A-A in FIG. 1;

FIG. 4 is a vertical cross sectional view along the line A-A in FIG. 1;

FIG. 5 is a vertical cross sectional view of a diode of a comparative example;

FIG. 6 is a vertical cross sectional view of a diode of a second embodiment; and

FIG. 7 is a vertical cross sectional view of the diode of the second embodiment.

### DETAILED DESCRIPTION

### First Embodiment

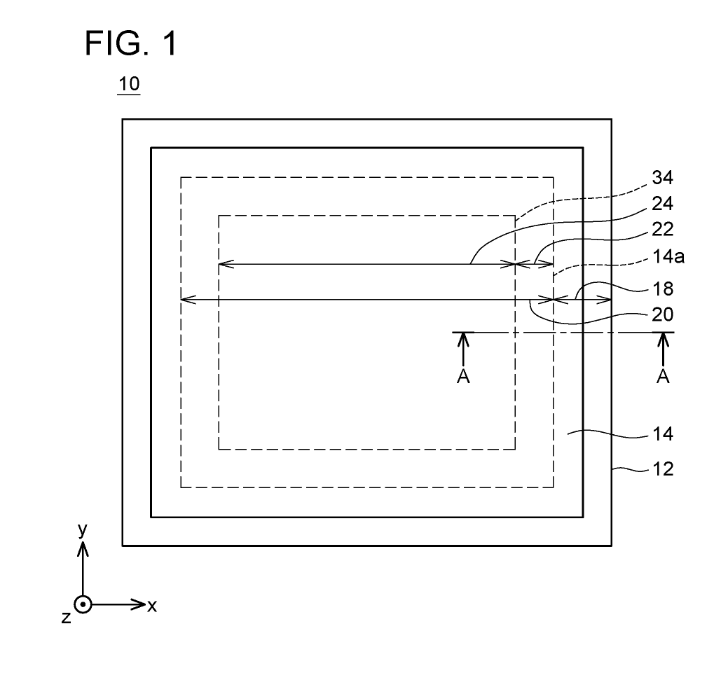

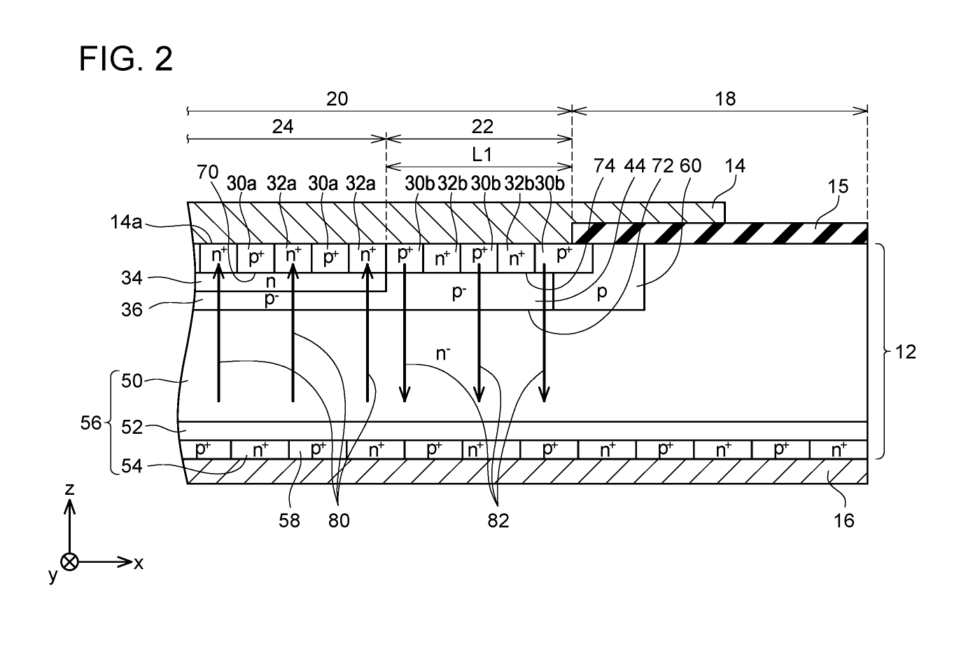

As shown in FIG. 1, a diode 10 of a first embodiment comprises a semiconductor substrate 12. Notably, hereinbelow, one direction parallel to a front surface of the semiconductor substrate 12 will be termed an x direction, a direction that is parallel to the front surface of the semiconductor substrate 12 and intersects vertically to the x direction will be termed a y direction, and a thickness direction of the semiconductor substrate 12 (that is, a direction intersecting vertically to both the x direction and the y direction) will be termed a z direction. An anode electrode 14 is provided on the front surface of the semiconductor substrate 12. As shown in FIG. 2, a peripheral portion of the front surface of the semiconductor substrate 12 is covered by an insulating film 15. The anode electrode 14 makes contact with the semiconductor substrate 12 in a region where no insulating film 15 is provided (central portion of the front surface of the semiconductor substrate 12). That is, a contact portion 14a where the anode electrode 14 and the semiconductor substrate 12 make contact with each other is provided at the central portion of the front surface of the semiconductor substrate 12. In the region where the insulating film 15 is provided (peripheral portion of the front surface of the semiconductor substrate 12), the anode electrode 14 is provided on the insulating film 15, and is not making contact with the semiconductor substrate 12. Hereinbelow, as shown in FIG. 1, a semiconductor region that overlaps with the contact portion 14a when the semiconductor substrate 12 is seen in its plan view along its thickness direction (that is, z direction) will be termed an element field 20. Further, a semiconductor region outside the element field 20 (that is, range covered by the insulating film 15) will be termed a peripheral field 18.

As shown in FIG. 2, a cathode electrode 16 is provided on a rear surface of the semiconductor substrate 12. The cathode electrode 16 covers an entirety of the rear surface of the semiconductor substrate 12. That is, the cathode electrode 16 is provided over a rear surface of the element field 20 and a rear surface of the peripheral field 18.

In a range of the element field 20 that is exposed in the contact portion 14a (that is, on the front surface of the semiconductor substrate 12), a plurality of anode regions 30 (that is, 30a 30b) and a plurality of pillar regions 32 (that is, 32a and 32b) are provided. Each of the anode regions 30 is a p-type region having a high p-type impurity concentration. Each of the anode regions 30 makes Ohmic contact with the anode electrode 14. Each of the anode regions 30 extends in an elongate shape along the y direction. Each of the pillar regions 32 is an n-type region with a high n-type impurity concentration. Each of the pillar regions 32 makes Ohmic contact with the anode electrode 14. However, the n-type impurity concentration of all of the pillar regions 32 may be adjusted to a low concentration, and the pillar regions 32 may be making Schottky contact with the anode electrode 14. Each of the pillar regions 32 extends in an elongate shape along the y direction. The anode regions 30 and the pillar regions 32 are disposed so that they appear alternately along the x direction at a surface layer portion exposed in the contact portion 14a. That is, the anode regions 30 and the pillar regions 32 are exposed alternately along the x direction at the front surface of the semiconductor substrate 12. The anode regions 30 and the pillar regions 32 are adjacent to one another.

An n-type barrier region 34 is provided under the anode regions 30 and the pillar regions 32 (on the rear surface side thereof). The barrier region 34 makes contact with the anode regions 30 and the pillar regions 32 from below. As shown in FIG. 1, the barrier region 34 is provided only in the central portion of the element field 20, and are not provided in the peripheral portion of the element field 20. That is, an interval is provided between the barrier region 34 and the peripheral field 18. Hereinbelow, as shown in FIG. I, a semiconductor region that overlaps with the barrier region 34 when the semiconductor substrate 12 is seen in its plan view along its thickness direction will be termed a cell field 24. Further, a range between the cell field 24 and the peripheral field 18 (that is, a range outside the cell field 24 and inside the element field 20) will be termed an intermediate field 22. Further, the anode regions 30 in the cell field 24 are termed first anode regions 30a, and the anode regions 30 in the intermediate field 22 are termed second anode regions 30b. Further, the pillar regions 32 in the cell field 24 are termed first pillar regions 32a, and the pillar regions 32 in the intermediate field 22 are termed second pillar regions 32b.

A first intermediate region 36 is provided under the barrier region 34. The first intermediate region 36 is a p-type region with a lower p-type impurity concentration than the anode regions 30. The first intermediate region 36 makes contact with the barrier region 34 from below. The first intermediate region 36 is separated from the first anode regions 30a by the barrier region 34.

As described above, no barrier region 34 is provided under the second anode regions 30b and the second pillar regions 32h in the intermediate field 22. In the intermediate field 22, a second intermediate region 44 is provided under the second anode regions 30b and the second pillar regions 32b. The second intermediate region 44 is a p-type region with a lower p-type impurity concentration than the anode regions 30. The second intermediate region 44 makes contact with the second anode regions 30b and the second pillar regions 32b from below. The second intermediate region 44 extends from a depth of lower ends of the second anode regions 30b and the second pillar regions 32b to a depth of a lower end of the first intermediate region 36 in the cell field 24. The second intermediate region 44 makes contact with the barrier region 34 and the first intermediate region 36 in the cell field 24. The p-type impurity concentration of the second intermediate region 44 is substantially equal to the p-type impurity concentration of the first intermediate region 36. That is, the second intermediate region 44 and the first intermediate region 36 are p-type regions that are substantially continuous.

Notably, a width Li of the intermediate field 22 (that is, interval between the barrier region 34 and the peripheral field 18 in the x direction) is longer than a diffusion length of holes in a drift region 50, as will be described later.

A terminating p-type region 60 is provided in the peripheral field 18. The terminating p-type region 60 is provided across the peripheral field 18 and the intermediate field 22. The terminating p-type region 60 extends from the front surface of the semiconductor substrate 12 to substantially the same depth as the lower end of the second intermediate region 44. The terminating p-type region 60 makes contact with the second anode region 30b that is on an outermost peripheral side and the second intermediate region 44.

An n-type cathode region 56 is provided under the first intermediate region 36, the second intermediate region 44, and the terminating p-type region 60. The cathode region 56 comprises a drift region 50, a buffer region 52, and a plurality of cathode contact regions 54.

The drift region 50 is an n-type region having a low n-type impurity concentration. The drift region 50 extends across the cell field 24, the intermediate field 22, and the peripheral field 18. The drift region 50 makes contact with the first intermediate region 36, the second intermediate region 44, and the terminating p-type region 60 from below, Further, the drift region 50 extends further out toward the peripheral side than the terminating p-type region 60, and is exposed on the front surface and a lateral end surface of the semiconductor substrate 12.

The buffer region 52 is an n-type region with a higher n-type impurity concentration than the drift region 50. The buffer region 52 is provided under the drift region 50. The buffer region 52 extends across the cell field 24, the intermediate field 22, and the peripheral field 18. The buffer region 52 makes contact with the drift region 50 from below in each of the cell field 24, the intermediate field 22, and the peripheral field 18.

The aforementioned plurality of cathode contact regions 54 and a plurality of electron suppression regions 58 are provided under the buffer region 52. The cathode contact regions 54 and the electron suppression regions 58 are provided in a range exposed on the rear surface of the semiconductor substrate 12. Each of the cathode contact regions 54 is an n-type region having a higher n-type impurity concentration than the buffer region 52. Each of the cathode contact regions 54 makes contact with the buffer region 52 from below. Each of the cathode contact regions 54 makes Ohmic contact with the cathode electrode 16. Each of the cathode contact regions 54 extends elongated along the y direction. Each of the electron suppression regions 58 is a p-type region with a high p-type impurity concentration. Each of the electron suppression regions 58 makes contact with the buffer region 52 from below. Each of the electron suppression regions 58 makes Ohmic contact with the cathode electrode 16. Each of the electron suppression regions 58 extends elongated along the y direction. The cathode contact regions 54 and the electron suppression regions 58 are disposed so that they appear alternately and repeatedly along the x direction. A striped structure of the cathode contact regions 54 and the electron suppression regions 58 is provided across the cell field 24, the intermediate field 22, and the peripheral field 18.

Next, an operation of the diode 10 will be described. Firstly, an operation of applying a forward voltage (voltage by which the anode electrode 14 comes to have a higher potential than the cathode electrode 16) to the diode 10 will be described.

When the forward voltage is gradually increased, electrons flow in the cell field 24 as shown by an arrow 80 in FIG. 2. That is, the electrons flow from the cathode electrode 16 into the drift region 50 through the cathode contact regions 54 and the buffer region 52. The electrons that had flown into the drift region 50 passes through the first intermediate region 36, enters the barrier region 34, then flows to the anode electrode 14 from the barrier region 34 through the first pillar regions 32a. Although the first intermediate region 36 is of the p-type, the impurity concentration thereof is low and a thickness thereof is thin, thus the electrons pass through the first intermediate region 36. As above, in a state where a relatively low forward voltage is being applied, the electrons flow from the barrier region 34 to the anode electrode 14 through the first pillar regions 32a, so a potential of the barrier region 34 becomes substantially equal to a potential of the anode electrode 14. Due to this, a potential difference is less likely to be generated in pn junctions 70 at interfaces of the first anode regions 30a and the barrier region 34. Thus, at this stage, the pn junctions 70 do not turn on.

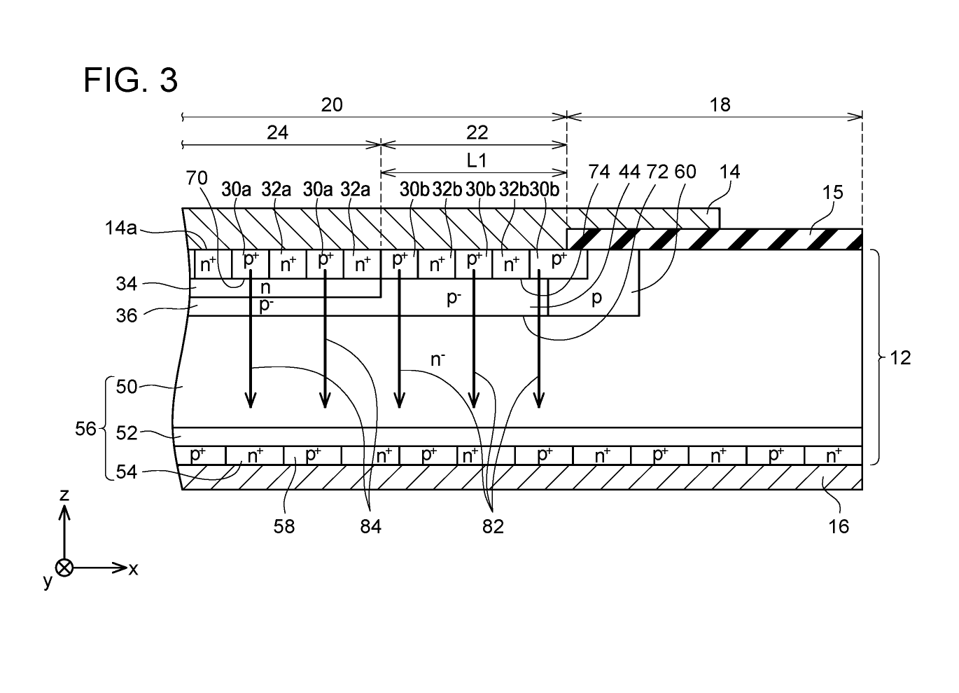

When the forward voltage is further increased, the electrons flowing in the cell field 24 as shown by the arrow 80 increases, and the potential difference between the barrier region 34 and the anode electrode 14 becomes larger. Consequently, the potential difference applied to the pn junctions 70 becomes large accompanying this increase in the potential difference. When the potential difference applied to the pn junctions 70 exceeds a predetermined value, the pn junctions 70 turn on. Then, as shown by an arrow 84 in FIG. 3, holes flow. That is, the holes flow from the anode electrode 14 into the drift region 50 through the first anode regions 30a, the barrier region 34, and the first intermediate region 36. Although the first intermediate region 36 is of the p-type, the impurity concentration thereof is low and the thickness thereof is thin, thus the holes pass through the first intermediate region 36. The holes that had flown into the drift region 50 flows to the cathode electrode 16 through the buffer region 52 and the cathode contact regions 54. Further, when the pn junctions 70 turn on, the electrons flow in an opposite direction of the arrow 84. That is, the electrons flow from the cathode electrode 16 into the drift region 50 through the cathode contact regions 54 and the buffer region 52. The electrons having flown into the drift region 50 flow to the anode electrode 14 through the first intermediate region 36, the barrier region 34, and the first anode regions 30a.

As described above, in the cell field 24, it is difficult for the potential difference to be generated in the pn junctions 70 with the electrons flowing through the barrier region 34 and the pillar regions 32 at the state where the forward voltage is still low. Thus, the pn junctions 70 turn on in a stage where the forward voltage has become sufficiently high. That is, the timing when the pn junctions 70 turn on becomes delayed. Due to this, the holes are suppressed from flowing into the drift region 50.

On the other hand, since no barrier region 34 is provided in the intermediate field 22, the flow of the electrons as shown by the arrow 80 in FIG. 2 is not generated in the intermediate field 22. In the intermediate field 22, the second anode regions 30b make direct contact with the second intermediate region 44, so a potential of the second intermediate region 44 becomes substantially equal to the potential of the anode electrode 14. Thus, when the forward voltage is increased, the potential difference is easily generated in a pn junction 72 at an interface between the second intermediate region 44 and the drift region 50. Due to this, in the intermediate field 22, the pn junction 72 turns on in the stage where the forward voltage is still relatively low. As a result, in the intermediate field 22, the holes flow along the arrow 82 shown in FIG. 2. That is, the holes flow from the anode electrode 14 into the drift region 50 through the second anode regions 30b and the second intermediate region 44. The holes that had flown into the drift region 50 flows to the cathode electrode 16 through the buffer region 52 and the cathode contact regions 54. Further, when the pn junction 72 turns on, the electrons flow in an opposite direction of the arrow 82. That is, the electrons flow from the cathode electrode 16 into the drift region 50 through the cathode contact regions 54 and the buffer region 52. The electrons having flown into the drift region 50 flow to the anode electrode 14 through the second intermediate region 44 and the second anode regions 30b. Thereafter, even if the forward voltage further increases, the current flows in the intermediate field 22 similar to the case where the forward voltage is low, as shown by the arrow 82 in FIG. 3. With the pn junction 72 of the intermediate field 22 and the pn junctions 70 of the cell field 24 turning on as shown in FIG. 3, the diode 10 thereby turns on.

As described above, in the intermediate field 22, the pn junction 72 turns on in the stage where the forward voltage is still relatively low. That is, the pn junction 72 of the intermediate field 22 turns on at an earlier timing than the pn junctions 70 of the cell field 24. Due to this, in the intermediate field 22, the inflow of the holes to the drift region 50 begins at an earlier timing than in the cell field 24. Thus, in the intermediate field 22, the holes are more easily flown to the drift region 50 than in the cell field 24.

Further, as shown in FIG. 3, when the holes flow into the drift region 50, some of the holes in the drift region 50 disperse to the peripheral field 18. Thus, in the state where the diode 10 is turned on, the holes are present in the drift region 50 in the peripheral field

Notably, the second anode regions 30b and the second pillar regions 32b are provided in a front layer part of the intermediate field 22 on an anode electrode 14 side (front surface side). Pn junctions 74 are provided at interfaces between the second pillar regions 32b and the second intermediate region 44. In the pn junctions 74, a barrier is small in a direction oriented from the second intermediate region 44 toward the second pillar regions 32b, but the barrier is large in a direction oriented from the second pillar regions 32b toward the second intermediate region 44. Thus, the holes that flow from the anode electrode 14 toward the drift region 50 in the intermediate field 22 flow via the second anode regions 30b as shown by the arrow 82, but hardly flow in the second pillar regions 32b. Accordingly, by providing the n-type second pillar regions 32b at portions of the surface layer part on the anode electrode 14 side of the intermediate field 22, the pathway through which the holes flow into the drift region 50 can be narrowed. Due to this, the inflow of the holes into the drift region 50 can be suppressed to some degree in the intermediate field 22 as well.

Further, in this diode, the cathode contact regions 54 and the electron suppression regions 58 are arranged alternately in a surface layer part on a cathode electrode 16 side (rear surface side). As described above, when the diode 10 turns on, the electrons flow in from the cathode electrode 16 to the drift region 50 through the cathode contact regions 54. The electrons flowing in from the cathode electrode 16 into the drift region 50 hardly flow in the electron suppression regions 58. As above, the pathways through which the electrons flow into the drift region 50 can be narrowed by disposing the p-type electron suppression regions 58 at portions of the surface layer part on the rear surface side of the semiconductor substrate 12. Due to this, the inflow of the electrons into the drift region 50 can be suppressed to some degree.

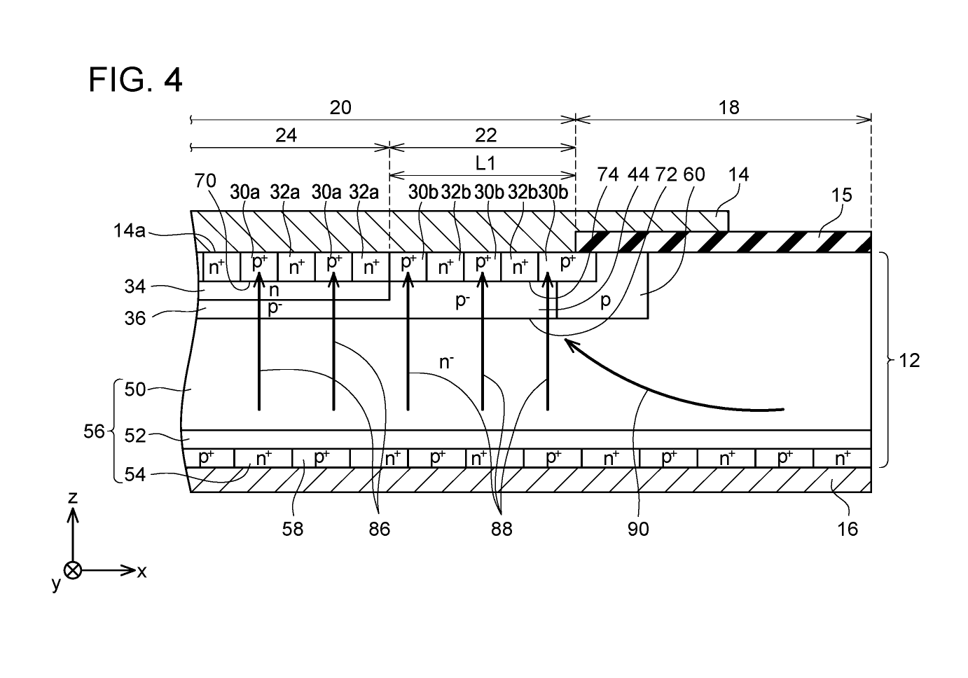

Next, an operation of the diode 10 in a case of switching the applied voltage of the diode 10 from the forward voltage to a reverse voltage (that is, a reverse recovery operation of the diode 10) will be described. As shown in FIG. 3, in the state where the diode 10 is turned on, the applied voltage is switched from the forward voltage to the reverse voltage. By so doing, the holes in the drift region 50 are discharged to the anode electrode 14 as shown by arrows 86, 88, and 90 in FIG. 4.

In the cell field 24, as shown by the arrow 86, the holes are discharged from the drift region 50 to the anode electrode 14 through the first intermediate region 36, the barrier region 34, and the anode regions 30. As aforementioned, in the cell field 24, the inflow of the holes to the drift region 50 is effectively suppressed upon the application of the forward voltage. Thus, the holes discharged to the anode electrode 14 from the drift region 50 upon the reverse recovery operation are small in amount. Thus, no high reverse recovery current flows in the cell field 24. Since the reverse recovery current flowing in the cell field 24 is small, the reverse recovery current flowing in the cell field 24 does not give much rise to the potential of the first intermediate region 36.

In the intermediate field 22, as shown by the arrow 88, the holes are discharged from the drift region 50 to the anode electrode 14 through the second intermediate region 44 and the second anode regions 30b. Further, the holes existing in the drift region 50 in the peripheral field 18 flow into the drift region 50 of the intermediate field 22 as shown by the arrow 90. The holes having flown into the intermediate field 22 through the peripheral field 18 also are discharged to the anode electrode 14 through the pathway shown by the arrow 88. Due to this, the reverse recovery current concentrates in the intermediate field 22. A high reverse recovery current flows in the intermediate field 22.

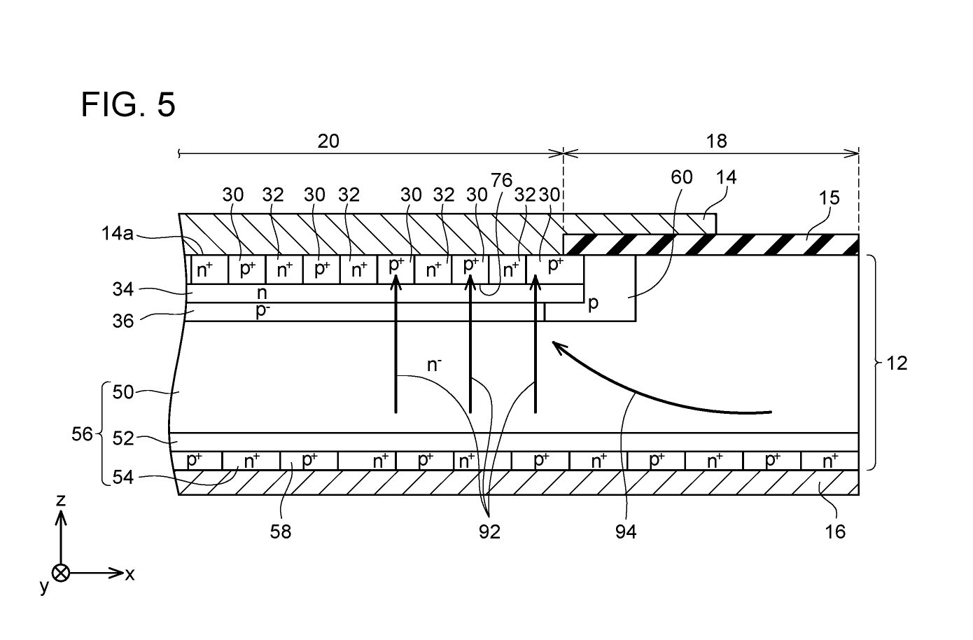

Here, for comparison, as shown in FIG. 5, a diode in which the barrier region 34 is provided on an entirety of the element field 20 will be considered. In this case as well, the reverse recovery current (holes) concentrate in the peripheral portion of the element field 20. In FIG. 5, the reverse recovery current flows in the peripheral part of the element field 20 as shown by the arrows 92, 94. The pathway shown by the arrow 92 passes through pn junctions 76 at interfaces between the barrier region 34 and the anode regions 30. A barrier of the pn junctions 76 is high against the holes flowing in the direction shown by the arrow 92, so if the reverse recovery current flows in the direction shown by the arrow 92, the potential of the p-type intermediate region 36 increases. The potential increase in the intermediate region 36 becomes prominent at a portion where the reverse recovery current concentrates (that is, at the portion of the element field 20 in a vicinity of the peripheral field 18). When the potential of the intermediate region 36 increases, a parasitic transistor (npn transistor) configured of the n-type barrier region 34, the p-type intermediate region 36, and the n-type cathode region 56 turns on. Then, a parasitic thyristor configured of the barrier region 34, the intermediate region 36, the cathode region 56, and the electron suppression regions 58 also turns on. As above, when the parasitic transistor and the parasitic thyristor turn on, the holes flow from the cathode electrode 16 into the semiconductor substrate 12 and the holes that had flown in further flows to the anode electrode 14. Further, the electrons flow from the anode electrode 14 to the semiconductor substrate 12, and the electrons that had flown in further flows to the cathode electrode 16. As above, the holes and electrons flow between the anode electrode 14 and the cathode electrode 16, and a high reverse recovery current flows. Due to this, a high loss is generated upon the reverse recovery operation.

Contrary to this, in the diode 10 of the first embodiment shown in FIG. 4, the barrier region 34 is not provided in the intermediate field 22, so the potential of the second intermediate region 44 does not increase so much even if the reverse recovery current shown by the arrow 88 flows. As a result, the potential of the first intermediate region 36 connected to the second intermediate region 44 does not increase so much. As above, the reverse recovery current flowing in the intermediate field 22 does not give much rise to the potential of the first intermediate region 36.

As described above, in the diode 10, the potential of the first intermediate region 36 does not so much rise upon the reverse recovery operation. Due to this, the parasitic transistor configured of the barrier region 34, the first intermediate region 36, and the cathode region 56 is suppressed from turning on. That is, the parasitic thyristor configured of the barrier region 34, the first intermediate region 36, the cathode region 56, and the electron suppression regions 58 is suppressed from turning on.

Further, as described above, in the intermediate field 22, the inflow of the holes into the drift region 50 is suppressed upon the application of the forward voltage by the second pillar regions 32b. Accordingly, the reverse recovery current flowing in the intermediate field 22 upon the reverse recovery operation is suppressed. Due to this as well, the increase in the potentials of the second intermediate region 44 and the first intermediate region 36 is suppressed, so the parasitic transistor and the parasitic thyristor are less likely to turn on.

Further, in the diode 10, a width L1 of the intermediate field 22 (that is, interval between the barrier region 34 and the peripheral field 18 in the x direction) is longer than a diffusion length of the holes in the drift region 50. Due to this, the holes in the drift region 50 of the peripheral field 18 do not reach the barrier region 34 during the reverse recovery operation. That is, the holes in the drift region 50 of the peripheral field 18 are not discharged to the anode electrode 14 through the barrier region 34. Due to this, the increase in the potential of the first intermediate region 36 is further suppressed from occurring. Due to this, the parasitic transistor and the parasitic thyristor are even less likely to turn on.

As above, by the parasitic transistor and the parasitic thyristor being suppressed from turning on, the loss generated upon the reverse recovery operation can be suppressed.

Further, upon the reverse recovery operation, the electrons present in the drift region 50 are discharged to the cathode electrode 16. The reverse recovery current flows also by the electrons discharged as such. However, in the diode 10 of the first embodiment, the inflow of the electrons into the drift region 50 from the cathode electrode 16 upon the application of the forward voltage is suppressed by the electron suppression regions 58. Thus, the electrons discharged to the cathode electrode 16 from the drift region 50 upon the reverse recovery operation is small in amount. Due to this as well, the loss upon the reverse recovery operation is suppressed.

As described above, in the diode 10 of the first embodiment, the barrier region 34 for suppressing the inflow of the holes to the drift region 50 is provided in the cell field 24, whilst such a region is not provided in the intermediate field 22. Due to this, even if the reverse recovery current is concentrated in the intermediate field 22, the increase in the potential of the second intermediate region 44 is less likely to occur. Further, in the intermediate field 22, the reverse recovery current itself is suppressed by the second pillar regions 32b, by which the increase in the potential of the second intermediate region 44 is further suppressed from occurring. Due to this, the increase in the potential of the first intermediate region 36 is suppressed, and the parasitic transistor is suppressed from turning on. As a result, the loss upon the reverse recovery operation is suppressed.

Notably, in the diode 10 of the aforementioned first embodiment, the second anode regions 30b and the second pillar regions 32b are provided alternately and repeatedly in the intermediate field 22. However, they may be disposed in any other arrangements so long as the second anode regions 30b and the second pillar regions 32b are provided on the surface layer part of the intermediate field 22 on the front surface side.

Further, in the diode 10 of the aforementioned first embodiment, the second anode regions 30b are provided at positions adjacent to the terminating p-type region 60. However, the second pillar regions 32b may be provided at the positions adjacent to the terminating p-type region 60. According to this configuration, the inflow of the holes to the drift region 50 of the peripheral filed 18 can effectively be suppressed upon the application of the forward voltage. Accordingly, the reverse recovery current flowing in the intermediate field 22 can be suppressed.

Further, in the diode 10 of the aforementioned first embodiment, a pitch by which the anode regions 30 and the pillar regions 32 are repeated in the x direction in the intermediate field 22 may be made shorter. For example, this pitch may be made shorter in the intermediate field 22 than that in the cell field 24. The holes that are discharged to the anode electrode 14 upon the reverse recovery operation flow to the second anode regions 30b by detouring around the second pillar regions 32b. By making the aforementioned pitch shorter, the pathways for the holes to flow upon detouring around the second pillar regions 32b are made shorter, so the increase in the potentials of the second intermediate region 44 and the first intermediate region 36 can further be suppressed more efficiently.

Relationships of the diode 10 of the first embodiment and the diode of the claims will be described. The first pillar regions 32a in the first embodiment are an example of claimed pillar regions. The second pillar regions 32b in the first embodiment are an example of a claimed hole suppression region (hole suppression region being an n-type region). The pn junctions 74 in the first embodiment are an example of a claimed barrier structure. The drift region 50 in the first embodiment is an example of a part of a claimed cathode region adjacent to a second intermediate region.

### Second Embodiment

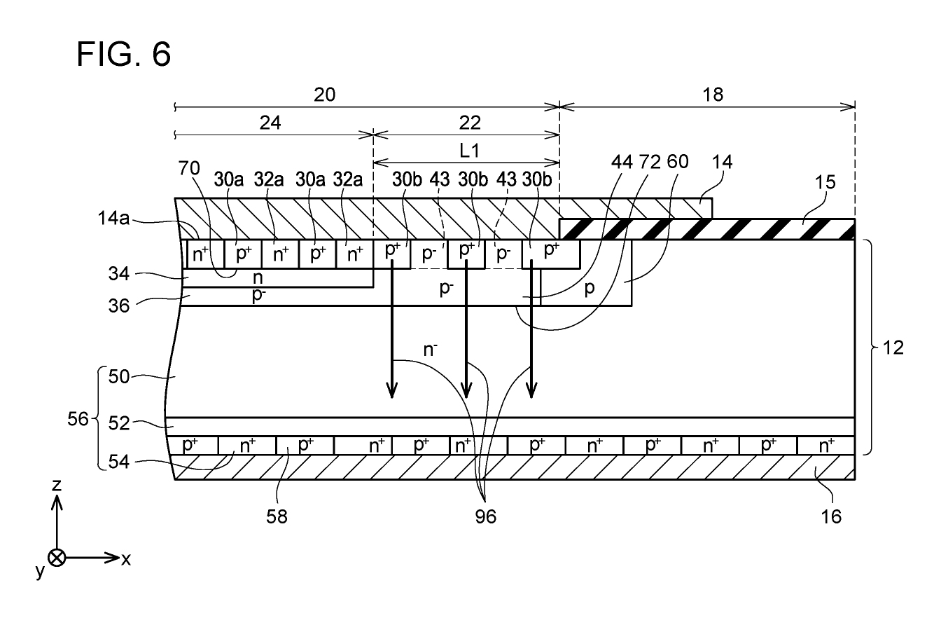

FIG. 6 shows a vertical cross sectional view of a diode of a second embodiment corresponding to FIG. 2. As is apparent from comparing FIG. 2 and FIG. 6, the diode of the second embodiment has Schottky regions 43 provided instead of the second pillar regions 32b (pillar regions 32 in the intermediate field 22) in the diode 10 of the first embodiment. Aside from this point, the structure of the diode of the second embodiment is equal to the structure of the diode 10 of the first embodiment.

A plurality Schottky regions 43 is provided in the intermediate field 22 of the diode of the second embodiment. Each of the Schottky regions 43 is a p-type region with a low p-type impurity concentration. The p-type impurity concentration of each of the Schottky regions 43 is lower than the p-type impurity concentration of the anode regions 30, and is substantially equal to the p-type impurity concentration of the second intermediate region 44. Each of the Schottky regions 43 makes Schottky contact with the anode electrode 14. Each of the Schottky regions 43 extends elongated along the y direction. The second anode regions 30b and the Schottky regions 43 are disposed so that they appear alternately and repeatedly along the x direction. The second anode regions 30b and the Schottky regions 43 are adjacent one another. The second intermediate region 44 is provided under the second anode regions 30b and the Schottky regions 43. The second intermediate region 44 makes contact with the second anode regions 30b and the Schottky regions 43 from below. As aforementioned, the Schottky regions 43 and the second intermediate region 44 have a substantially equaling p-type impurity concentration, so the Schottky regions 43 and the second intermediate region 44 are p-type regions that are substantially continuous.

Next, an operation of the diode of the second embodiment will be described. A case of gradually increasing the forward voltage to be applied to the diode of the second embodiment will be considered. The cell field 24 of the second embodiment operates similar to the cell field 24 of the first embodiment. Thus, upon applying the forward voltage, the holes are suppressed from flowing into the drift region 50 of the cell field 24 by the barrier region 34. On the other hand, no barrier region 34 is provided in the intermediate field 22, so the second anode regions 30b make direct contact with the second intermediate region 44. Due to this, the potential of the second intermediate region 44 becomes substantially equal to the potential of the anode electrode 14. Thus, the potential difference is easily generated in the pn junction 72 at the interface between the second intermediate region 44 and the drift region 50. Due to this, in the intermediate field 22, the pn junction 72 turns on in the stage where the forward voltage is still relatively low. As a result, in the intermediate field 22, the holes flow along an arrow 96 shown in FIG. 6. That is, the holes flow from the anode electrode 14 into the drift region 50 through the second anode regions 30b and the second intermediate region 44. The holes that had flown into the drift region 50 flows to the cathode electrode 16. Further, when the pn junction 72 turns on, the electrons flow in an opposite direction of the arrow 96.

As described above, in the intermediate field 22, the pn junction 72 turns on in the stage where the forward voltage is still relatively low, and the holes and electrons flow. That is, the pn junction 72 of the intermediate field 22 turns on at an earlier timing than the pn junctions 70 of the cell field 24. Due to this, in the intermediate field 22, the inflow of the holes to the drift region 50 begins at an earlier timing than in the cell field 24. Thus, in the intermediate field 22, the holes are more easily flown to the drift region 50 than in the cell field 24.

Notably, the second anode regions 30b and the Schottky regions 43 are provided in the front layer part of the intermediate field 22 on the anode electrode 14 side (front surface side). Schottky junctions are generated at the interfaces of the Schottky regions 43 and the anode electrode 14. In the Schottky junctions, the barrier is small in a direction oriented from the Schottky regions 43 toward the anode electrode 14, but the barrier is large in a direction oriented from the anode electrode 14 toward the Schottky regions 43. Thus, the holes that flow from the anode electrode 14 toward the drift region 50 when the pn junction 72 in the intermediate field 22 is turned on flow via the second anode regions 30h as shown by the arrow 96, but hardly flow in the Schottky regions 43. Accordingly, by providing the Schottky regions 43 at portions of the surface layer part on the anode electrode 14 side of the intermediate field 22, the pathway through which the holes flow into the drift region 50 can be narrowed. Due to this, the inflow of the holes into the drift region 50 can be suppressed to some degree in the intermediate field 22 as well.

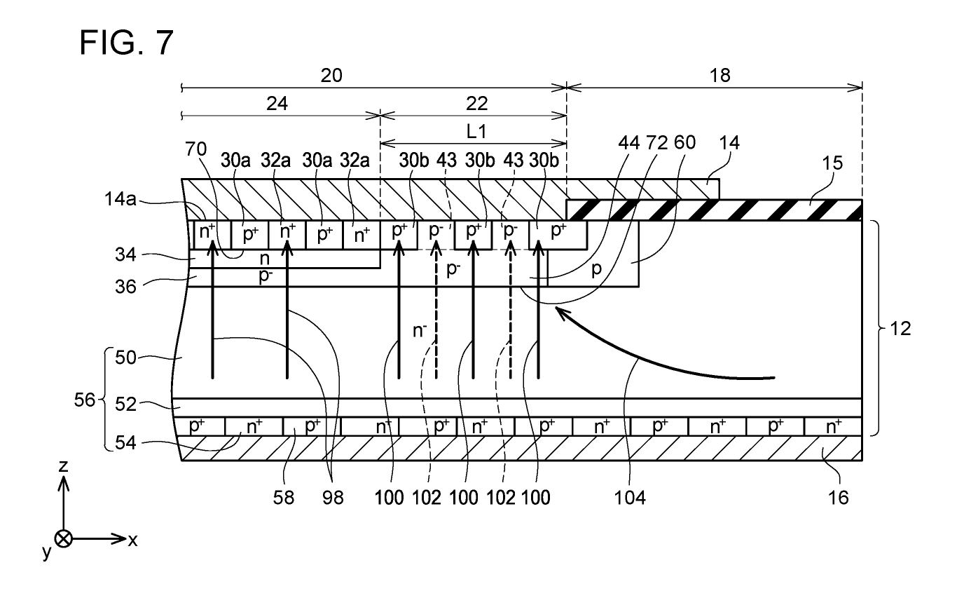

Next, an operation of the diode in the case of switching the applied voltage of the diode of the second embodiment from the forward voltage to the reverse voltage will be described in the state where the diode is turned on, the applied voltage is switched from the forward voltage to the reverse voltage. By so doing, the holes in the drift region 50 are discharged to the anode electrode 14 as shown by arrows 98, 100, 102, and 104 in FIG. 7.

In the cell field 24, the holes are discharged as shown by the arrow 98. In the reverse recovery operation as well, the cell field 24 of the second embodiment operates similar to the cell field 24 of the first embodiment.

In the intermediate field 22, the holes are discharged from the drift region 50 to the anode electrode 14 through the second intermediate region 44 and the anode regions 30 as shown by the arrow 100.

Further, some of the holes in the intermediate field 22 flow into the Schottky regions 43 from the drift region 50 through the second intermediate region 44 as shown by the arrow 102. A very thin depletion layer is generated in a vicinity of the front surfaces of the Schottky regions 43 (in the vicinity of the Schottky junctions). When the holes reach this depletion layer, the holes are discharged to the anode electrode 14 due to the strong electric field in the depletion layer. As above, in the diode of the second embodiment, the holes flow also in the pathway shown by the arrow 102.

Further, the holes existing in the drift region 50 of the peripheral field 18 flow into the drift region 50 of the intermediate field 22 as shown by the arrow 104. The holes having flown into the intermediate field 22 through the peripheral field 18 as above also are discharged to the anode electrode 14 through the pathways shown by the arrows 100, 102. Due to this, the reverse recovery current concentrates in the intermediate field 22. A high reverse recovery current flows in the intermediate field 22.

however, in the diode of the second embodiment, the barrier region 34 is not provided in the intermediate field 22, so the potential of the second intermediate region 44 does not increase so much even if the reverse recovery current shown by the arrows 100, 102, 104 flows. Further, in the diode of the second embodiment, both the anode regions 30 and the Schottky regions 43 are configured as the pathways to discharge the holes, so the pathways for discharging the holes is wide as compared to that in the first embodiment. Thus, the holes are more easily discharged to the anode electrode 14, by which the increase in the potential of the second intermediate region 44 is less likely to occur. Since the potential of the second intermediate region 44 is less likely to increase, the potential of the first intermediate region 36 connected to the second intermediate region 44 does not increase so much. Due to this, the parasitic transistor configured of the barrier region 34, the first intermediate region 36, and the cathode region 56 is suppressed from turning on. That is, the parasitic thyristor configured of the barrier region 34, the first intermediate region 36, the cathode region 56, and the electron suppression regions 58 is suppressed from turning on. As a result, the loss generated upon the reverse recovery operation is suppressed.

Further, as described above, in the diode of the second embodiment, the inflow of the holes into the drift region 50 of the intermediate field 22 is suppressed upon the application of the forward voltage by the Schottky regions 43. Accordingly, the reverse recovery current flowing in the intermediate field 22 upon the reverse recovery operation is suppressed. Due to this as well, the increase in the potentials of the second intermediate region 44 and the first intermediate region 36 is suppressed, so the parasitic transistor and the parasitic thyristor are less likely to turn on.

Accordingly, in the diode of the second embodiment as well, the loss generated upon the reverse recovery operation can be suppressed by suppressing the parasitic transistor and the parasitic thyristor from turning on.

Further, in the diode of the second embodiment as well, the inflow of the electrons into the drift region 50 from the cathode electrode 16 upon the application of the forward voltage is suppressed by the electron suppression regions 58. Thus, the electrons discharged to the cathode electrode 16 from the drift region 50 upon the reverse recovery operation is small in amount. Due to this as well, the loss upon the reverse recovery operation is suppressed.

As described above, in the diode of the second embodiment, the barrier region 34 is provided in the cell field 24, whilst such a region is not provided in the intermediate field 22. Due to this, even if the reverse recovery current is concentrated in the intermediate field 22, the increase in the potential of the second intermediate region 44 is less likely to occur. Further, in the intermediate field 22, the reverse recovery current itself is suppressed by the Schottky regions 43, by which the increase in the potential of the second intermediate region 44 is further suppressed from occurring. Due to this, the increase in the potential of the first intermediate region 36 is suppressed, and the parasitic transistor is suppressed from turning on. As a result, the loss upon the reverse recovery operation is suppressed.

Further, in the diode of the second embodiment, the p-type Schottky regions 43 are provided instead of the pillar regions 32 (n-type regions) in the first embodiment. Since there is no need to provide n-type regions in a range surrounded by the anode regions 30 and the second intermediate region 44, a number of pn junctions inside the semiconductor substrate 12 can be reduced. Due to this, a number of parasitic elements inside the semiconductor substrate 12 is reduced, and an unintended operation of the parasitic elements can be suppressed.

Notably, in the diode of the aforementioned second embodiment, the second anode regions 30b and the Schottky regions 43 are provided alternately and repeatedly in the intermediate field 22. However, they may be disposed in any other arrangements so long as the second anode regions 30b and the Schottky regions 43 are provided on the surface layer part of the intermediate field 22 on the front surface side.

Further, in the diode of the aforementioned second embodiment, one of the second anode regions 30b is provided at a position adjacent to the terminating p-type region 60. However, the Schottky regions 43 may be provided at the positions adjacent to the terminating p-type region 60. According to this configuration, the inflow of the holes to the drift region 50 of the peripheral filed 18 can effectively be suppressed upon the application of the forward voltage. Accordingly, the reverse recovery current flowing in the intermediate field 22 can be suppressed.

Relationships of the d diode of the second embodiment and the diode of the claims will be described. The first pillar regions 32a in the second embodiment are an example of claimed pillar regions. The Schottky regions 43 in the second embodiment are an example of a claimed hole suppression region (hole suppression region being a p-type region making Schottky contact with the anode electrode). The Schottky junctions in the second embodiment are an example of a claimed barrier structure. The drift region 50 in the second embodiment is an example of a part of a claimed cathode region adjacent to a second intermediate region.

Notably, in the aforementioned first and second embodiments, a diode is provided in the semiconductor substrate 12, however, an IGBT may be provided in addition to the diode in the semiconductor substrate 12. In this case, the anode electrode 14 may serve also as an emitter electrode of the IGBT, and the cathode electrode 16 may serve also as a collector electrode of the IGBT. Further in this case, the p-type electron suppression regions 58 may function also as collector regions of the IGBT.

Further, in the aforementioned first and second embodiments, the diode comprises the electron suppression regions 58, however, it may not be provided with the electron suppression regions 58. For example, a cathode contact region 54 may be provided in an entire range exposed on the rear surface of the semiconductor substrate 12.

Further, in the aforementioned first and second embodiments, a contact width in the x direction of the second anode region 30b adjacent to the terminating p-type region 60 (width of the region making contact with the anode electrode 14) may be set wider than that of other second anode regions 30b. Due to this, the holes flowing into the intermediate field 22 from the peripheral field 18 upon the reverse recovery operation is more easily discharged to the anode electrode 14, so the increase in the potentials of the second intermediate region 44 and the first intermediate region 36 can be suppressed more effectively.

Further, in the aforementioned first and second embodiments, the plurality of anode regions 30 and the plurality of pillar regions 32 are provided on the surface layer part of the cell field 24 on the front surface side. However, each of the anode regions 30 may be connected to each other at positions that are not shown, and each of the pillar regions 32 may be connected to each other at positions that are not shown. That is, so long as the striped structure of the anode regions 30 and pillar regions 32 is formed in a particular cross section, a single anode region 30 may be provided in the cell field 24, and a single pillar region 32 may be provided in the cell field 24.

The embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

What is claimed is:

1. A diode comprising:
a semiconductor substrate;
an anode electrode disposed on a front surface of the semiconductor substrate; and
a cathode electrode disposed on a rear surface of the semiconductor substrate,
wherein
the semiconductor substrate comprises, in a plan view:
a cell field;
an intermediate field located outside the cell field; and
a peripheral field located outside the intermediate field,
the anode electrode is in contact with the front surface of the semiconductor substrate in the cell field and the intermediate field, but is not in contact with the front surface of the semiconductor substrate in the peripheral field,
the cell field comprises:
at least one first anode region being of a p-type and in Ohmic contact with the anode electrode, the first anode region including portions exposed on the front surface of the semiconductor substrate;
at least one pillar region being of an n-type and in contact with the anode electrode, the pillar region including portions exposed on the front surface of the semiconductor substrate, the portions of the first anode region and the portions of the pillar region are alternately exposed on the front surface when viewed in a specific section of the semiconductor substrate;
a barrier region being of the n-type and in contact with the portions of the first anode region and the portions of the pillar region from a rear surface side; and
a first intermediate region being of the p-type, in contact with the barrier region from the rear surface side, and separated from the first anode region by the barrier region,
the intermediate field comprises:
a second anode region being of the p-type and in Ohmic contact with the anode electrode;
a hole suppression region being in contact with the anode electrode; and
a second intermediate region being of the p-type, in contact with the second anode region and the hole suppression region from the rear surface side, and in contact with the first intermediate region,
the barrier region is not located in the intermediate field,
a barrier structure is provided on a pathway from the anode electrode to the second intermediate region via the hole suppression region,
in the barrier structure, a barrier in a direction from the anode electrode toward the second intermediate region is larger than a barrier in a direction from the second intermediate region toward the anode electrode, and
a cathode region being of the n-type, in contact with the first intermediate region and the second intermediate region from the rear surface side, and in contact with the cathode electrode is provided in a range across the cell field, the intermediate field, and the peripheral field.

2. The diode of claim 1, wherein the hole suppression region is of the n-type.

3. The diode of claim 1, wherein the hole suppression region is of the p-type and is in Schottky contact with the anode electrode.

4. The diode of claim 1, wherein a width of the intermediate field is larger than a hole diffusion length of the cathode region at a part of the cathode region adjacent to the second intermediate region.
